(19) United States
(12) Patent Application Publication
(10) Pub. No.: US 2022/0130648 A1
(43) Pub. Date: Apr. 28, 2022

(54) SUBSTRATE TREATING APPARATUS AND SUBSTRATE TRANSFERRING METHOD

(71) Applicant: SEMES CO., LTD., Cheonan-si (KR)

(72) Inventor: Seung Bae LEE, Hwaseong-si (KR)

(73) Assignee: SEMES CO., LTD., Cheonan-si (KR)

(21) Appl. No.: 17/498,194

(22) Filed: Oct. 11, 2021

(30) Foreign Application Priority Data
Oct. 27, 2020 (KR) 10-2020-0140456

(51) Int. Cl. H01J 37/32; H01L 21/67; H01L 21/683; H01L 21/687

(52) U.S. Cl. CPC H01J 37/32715; H01L 21/67196; H01L 21/67201; H01L 21/6831; H01L 21/68707; H01L 21/68721; H01J 2237/334; H01J 37/32642; H01J 37/32743; H01J 37/32788; H01J 2237/20235; H01J 2237/2007; H01L 21/68742

(57) ABSTRACT

The inventive concept provides a substrate treating apparatus. The substrate includes a process chamber in which a substrate is treated, and a transfer robot that transfers the substrate and a focusing ring provided in a treatment space of the process chamber to the treatment space and having a hand, wherein the process chamber includes a treatment container that provides the treatment space, a chuck having a support surface supporting the substrate in the treatment space, and a lift pin module that lifts a lower surface of the focusing ring in a state in which the substrate is supported by the focusing ring, and the chuck is provided as a blocking plate in which a lift pin hole is not formed.

### CROSS-REFERENCE TO RELATED APPLICATIONS

A claim for priority under 35 U.S.C. § 119 is made to Korean Patent Application No. 10-2020-0140456 filed on Oct. 27, 2020, in the Korean Intellectual Property Office, the entire contents of which are hereby incorporated by reference.

### BACKGROUND

Embodiments of the inventive concept described herein relate to a substrate treating apparatus and a substrate transferring method.

Plasma refers to an ionized gaseous state including ions, radicals, electrons, and the like. The plasma is generated by very high temperature, strong electric fields, or radio frequency (RF) electromagnetic fields. A semiconductor device manufacturing process may include an etching process of removing a thin film formed on a substrate, such as a wafer, using plasma. The etching process is performed as ions and/or radicals contained in the plasma collide with a thin film on the substrate or react with the thin film.

A substrate treating apparatus using such plasma includes a process chamber, a support chuck (for example, an electrode static chuck (ESC)) that supports a substrate in the process chamber and is connected to an RF power source, and a focusing ring that surrounds an outer periphery of the substrate seated on the support chuck. The focusing ring is installed to distribute the plasma on a surface of the substrate with a high uniformity, and is etched together with the substrate with the plasma. When the substrate is repeatedly etched, the focusing ring also is etched so that the shape of the focusing ring gradually changes. A direction, in which ions and/or radicals are incident to the substrate, is changed according to a change in the shape of the focusing ring, and thus the etching characteristics of the substrate are changed. Accordingly, when a specific number or more of substrates are etched or the shape of the focusing ring is changed to deviate from an allowable range, it is necessary to replace the focusing ring.

The focusing ring is replaced as a transfer robot carries out the used focusing ring from the process chamber and carries the focusing ring into a ring pod, and thereafter, carries out a new focusing ring from the ring pod and carries the focusing ring into the process chamber. Further, such replacement of the focusing ring is performed separately from transfer of the substrate. Further, the process chamber is provided with the focusing ring that is transferred by a hand of the transfer robot and a lift pin module that may seat the substrate on the support chuck. In general, the process chamber is provided with a ring lift pin module that lifts the focusing ring and a substrate lift pin module that lifts the substrate. Further, a substrate lift pin of the substrate lift pin module is moved through a plurality of pin holes formed in a central region of the support chuck so that only the substrate among the focusing ring and the substrate may be moved.

However, in this way, in a structure in which the pin holes are formed in the support chuck connected to the RF power source, when RF power is applied to the support chuck, arcing is likely to occur in the pin holes. Further, since both the substrate lift pin module and the ring lift pin module are provided, a space occupied by a driving unit that is provided below the support chuck and drives the substrate lift pins and ring lift pins is very large. Further, when the support chuck chucks the substrate using an electrostatic force, and the substrate lift pin lifts the substrate from the support chuck in a state in which the support chuck is not properly discharged, the substrate may be twisted or cracked.

### SUMMARY

Embodiments of the inventive concept provide a substrate treating apparatus and a substrate transferring method capable of efficiently treating a substrate.

Embodiments of the inventive concept also provide a substrate treating apparatus and a substrate transferring method capable of minimizing the occurrence of an arcing phenomenon.

Embodiments of the inventive concept also provide a substrate treating apparatus and a substrate transferring method capable of minimizing the attachment of impurities to a chuck of the substrate treating apparatus or effectively cleaning the chuck.

Embodiments of the inventive concept also provide a substrate treating apparatus and a substrate transferring method capable of minimizing twisting or cracking of a substrate when the substrate is lifted from a chuck.

The aspect of the inventive concept is not limited thereto, and other unmentioned aspects of the present invention may be clearly appreciated by those skilled in the art from the following descriptions.

The inventive concept provides a substrate treating apparatus. The substrate treating apparatus includes a process chamber in which a substrate is treated, and a transfer robot that transfers the substrate and a focusing ring provided in a treatment space of the process chamber to the treatment space and has a hand, wherein the process chamber includes a treatment container that provides the treatment space, a chuck having a support surface supporting the substrate in the treatment space, and a lift pin module that lifts a lower surface of the focusing ring in a state in which the substrate is supported by the focusing ring, and the chuck is provided as a blocking plate in which a lift pin hole is not formed.

According to an embodiment, the treatment container may have an inlet port in which the focusing ring and the substrate are carried, the substrate treating apparatus may further include a controller, and the controller may control the transfer robot and the lift pin module so that, when the substrate is carried into the treatment space or carried out from the treatment space, the substrate passes through the inlet port in a state in which the hand supports the lower surface of the focusing ring that supports the substrate.

According to an embodiment, the treatment container may have an inlet port in which the focusing ring and the substrate are carried, the substrate treating apparatus may further include a controller, and the controller may control the transfer robot and the lift pin module so that, when the substrate passes through the inlet port, the substrate always passes through the inlet port while being supported by the focusing ring.

According to an embodiment, the lift pin module may include a lift pin disposed so as not to overlap the chuck when viewed from a top, and a pin drive unit that vertically moves the lift pin.

According to an embodiment, the process chamber may further include an insulation plate disposed below the chuck.

According to an embodiment, a height of an inner upper surface of the focusing ring may be smaller than a height of an outer upper surface of the focusing ring, and thus a lower surface of an edge region of the substrate may be placed on the inner upper surface of the focusing ring.

According to an embodiment, the focusing ring may have an inclined surface inclined upward in a direction from a center of the substrate to an outside of the substrate between the inner upper surface and the outer upper surface of the focusing ring.

According to an embodiment, the substrate treating apparatus may further include a buffer chamber that seats the substrate on the focusing ring or separates the focusing ring and the substrate from each other.

According to an embodiment, the buffer chamber may include a support plate having a seating surface on which the focusing ring is seated, a first lift pin that is disposed at a central region of the support plate when viewed from a top and lifts the substrate, and a second lift pin that is disposed at an edge region of the support plate when viewed from the top and lifts the focusing ring.

According to an embodiment, the buffer chamber may further include a support shelf accommodating the focusing ring.

According to an embodiment, the substrate treating apparatus may further include a transfer chamber in which the transfer robot is provided, wherein the process chamber and the buffer chamber are connected to the transfer chamber.

According to an embodiment, the substrate treating apparatus may further include an index unit including a load pot on which a container that accommodates the substrate and/or the focusing ring is seated and an index chamber connected to the load pot, and a process executing unit having the process chamber, a transfer chamber in which the transfer robot is provided, and a load lock chamber disposed between the index chamber and the transfer chamber, wherein the buffer chamber is connected to the index chamber.

Further, the inventive concept provides a substrate treating apparatus. The substrate treating apparatus includes a process chamber in which a substrate is treated, a transfer robot that is transfer the substrate and a ring member provided in a treatment space of the process chamber to the treatment space and has a hand, and a controller, wherein the process chamber includes a treatment container that provides the treatment space and has an inlet port in which the substrate and the ring member are carried, a chuck having a support surface for supporting the substrate in the treatment space, and a lift pin module that pushes a lower surface of the ring member upward in a state in which the substrate is supported by the ring member, and the controller controls the transfer robot and the lift pin module so that, when the substrate is carried in the treatment space or is carried out from the treatment space, the substrate always passes through the inlet port while being supported by the ring member.

According to an embodiment, the lift pin module may include a lift pin disposed so as not to overlap the chuck when viewed from a top, and a pin drive unit that vertically moves the lift pin.

According to an embodiment, the substrate treating apparatus may further include a buffer chamber that seats the substrate on the ring member or separates the substrate from the ring member.

According to an embodiment, the buffer chamber may include a support plate having a seating surface on which the ring member is seated, a first lift pin that is disposed in a central region of the support plate when viewed from a top and pushes a lower surface of the substrate upward, and a second lift pin that is disposed in an edge region of the support plate when viewed from the top and pushes the lower surface of the ring member upward.

Further, the inventive concept provides a substrate treating method of transferring a substrate. A substrate transferring method of transferring a substrate to a treatment space of a process chamber in which the substrate is treated using plasma may be provided in which a transfer robot carries the substrate into the treatment space of the process chamber or carries out the substrate from the treatment space, and when the transfer robot carries the substrate into the treatment space or carries out the substrate from the treatment space, the substrate is always carried into the treatment space while being seated on the ring member and the substrate is always carried out from the treatment space while being seated on the ring member.

According to an embodiment, when the transfer robot carries out the substrate from the treatment space, a lift pin of the process chamber may be raised to push upward a lower surface of the ring member on which the substrate is seated, a hand of the transfer robot may be moved into a lower portion of the ring member, and the lift pin may be lowered to seat the ring member, on which the substrate is seated, on an upper surface of the hand.

According to an embodiment, when the transfer robot carries the substrate into the treatment space, a hand of the transfer robot may be moved into the treatment space while supporting the ring member on which the substrate is seated, a lift pin of the process chamber may be raised to support a lower surface of the ring member on which the substrate is seated, and the lift pin may be lowered to seat the substrate on a support surface of a chuck of the process chamber.

According to an embodiment, the ring member may be a focusing ring that is a consumable component provided in the process chamber.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a plan view schematically illustrating a substrate treating apparatus according to an embodiment of the inventive concept;

FIG. 2 is a view illustrating a first container of FIG. 1;

FIG. 3 is a view illustrating a second container of FIG. 1;

FIG. 4 is a view illustrating the substrate treating apparatus provided in a process chamber of FIG. 1;

FIGS. 5 to 8 are views illustrating a state in which a substrate and a ring member are carried out from a treatment container of FIG. 4;

FIG. 9 is a view illustrating the substrate treating apparatus provided in a buffer chamber of FIG. 4;

FIGS. 10 to 17 are views illustrating a state in which the substrate and the ring member are separated from a housing of FIG. 6; and

FIG. 18 is a plan view schematically illustrating a substrate treating apparatus according to another embodiment.

### DETAILED DESCRIPTION

Hereinafter, exemplary embodiments of the inventive concept will be described in detail with reference to the accompanying drawings so that those skilled in the art to which the inventive concept pertains may easily carry out the inventive concept. However, the inventive concept may be implemented in various different forms, and is not limited to the embodiments. Further, in a description of the embodiments of the inventive concept, a detailed description of related known functions or configurations will be omitted when they make the essence of the inventive concept unnecessarily unclear. In addition, the same reference numerals are used for parts that perform similar functions and operations throughout the drawings.

The expression of ‘including’ some elements may mean that another element may be further included without being excluded unless there is a particularly contradictory description. In detail, the terms “including” and “having” are used to designate that the features, the numbers, the steps, the operations, the elements, the parts, or combination thereof described in the specification are present, and may be understood that one or more other features, numbers, step, operations, elements, parts, or combinations thereof may be added.

Singular expressions include plural expressions unless clearly otherwise indicated in the context. Further, in the drawings, the shapes and sizes of the elements may be exaggerated for clearer description.

The terms such as first and second may be used to describe various elements, but the elements are not limited to the terms. The terms may be used only for the purpose of distinguishing one element from another element. For example, while not deviating from the scope of the inventive concept, a first element may be named a second element, and similarly, the second element may be named the first element.

When it is mentioned that one element is “connected to” or “electrically connected to” another element, it should be understood that the first element may be directly connected or electrically connected to the second element but a third element may be provided therebetween. On the other hand, when it is mentioned that an element is “directly connected to” or “directly electrically connected to” another element, it should be understood that a third element is not present between them. It should be construed that other expressions that describe the relationships between elements, such as “between”, “directly between”, “adjacent to”, and “directly adjacent to” may have the same purpose.

In addition, unless defined otherwise, all terms used herein, including technical or scientific terms, have the same meanings as those generally understood by those skilled in the art to which the inventive concept pertains. The terms defined in the generally used dictionaries should be construed as having the meanings that coincide with the meanings of the contexts of the related technologies, and should not be construed as ideal or excessively formal meanings unless clearly defined in the specification of the inventive concept.

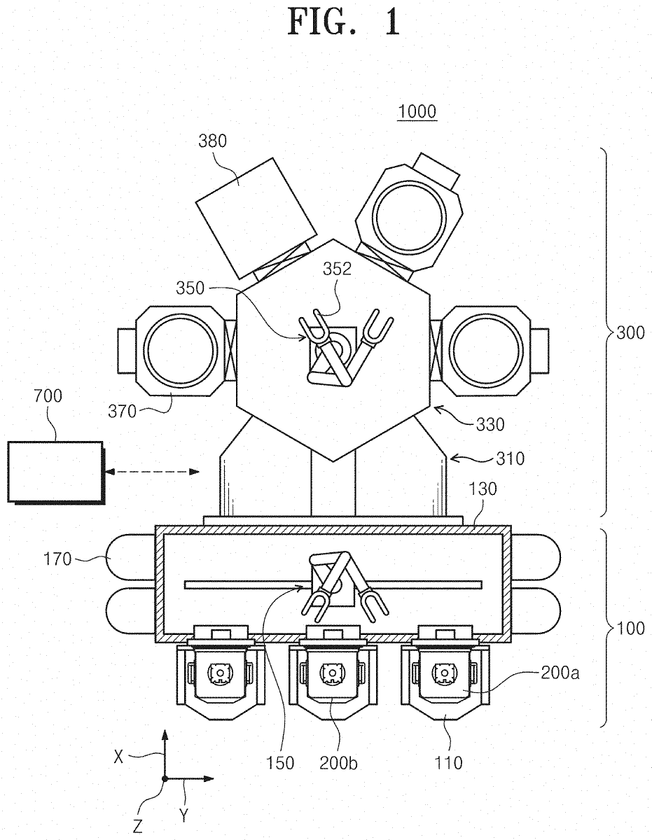

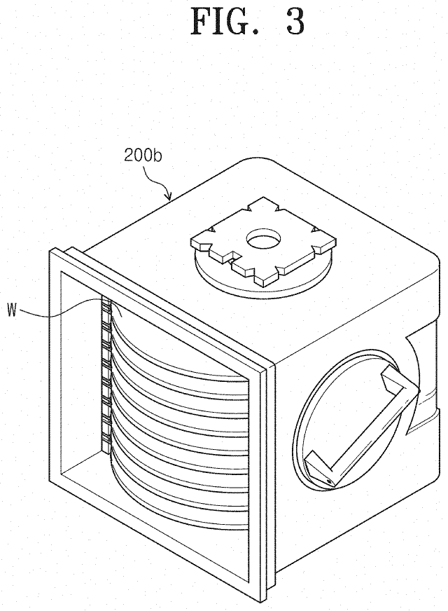

Hereinafter, embodiments of the inventive concept will be described with reference to FIGS. 1 to 15.

FIG. 1 is a plan view schematically illustrating a substrate treating apparatus according to an embodiment of the inventive concept. Referring to FIG. 1, a substrate treating apparatus 1000 according to an embodiment of the inventive concept may include an index unit 100, a process executing unit 300, and a controller 700. The index unit 100 and the process executing unit 300 may be arranged along a first direction “X” when viewed from the top. Hereinafter, a direction that is perpendicular to the first direction “X” when viewed from the top is defined as a second direction “Y”. Further, a direction that is perpendicular to the first direction “X” and the second direction “Y” is defined as a third direction “Z”. Here, the third direction “Z” may refer to a direction that is perpendicular to a ground surface.

The index unit 100 may include a load pot 110, an index chamber 130, a first transfer robot 150, and a side buffer 170.

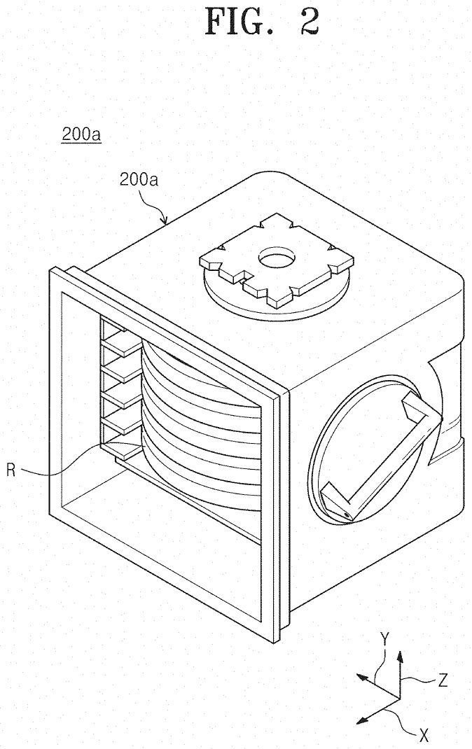

Containers 200a and 200b may be seated in the load pot 110. Various kinds of containers 200a and 200b may be seated in the load pot 110. For example, various kinds of containers 200a and 200b that accommodate different articles may be seated in the load pot 110. For example, as illustrated in FIG. 2, a ring member “R” may be accommodated in the first container 200a among the containers 200a and 200b. The ring member “R” may be a process kit in which a process chamber 370, which will be described above, may be provided. For example, the ring member “R” may be any one of an IOS ring, a quartz ring, and a focusing ring. Hereinafter, it will be described as an example that the ring member “R” is a focusing ring. Further, the second container 200b among the containers 200a and 200b may accommodate a substrate “W” that is a to-be-treated object treated in the process chamber 370, which will be described below. The substrate “W” may be a wafer.

Further, it has been described in the above example that the first container 200a accommodates the ring member “R” and the second container 200b accommodates the substrate “W”, but the inventive concept is not limited thereto. For example, the first container 200a may accommodate the substrate “W”, and the second container 200b may accommodate the ring member “R”. Further, the first container 200a may accommodate the substrate “W” and the ring member “R”. Further, the second container 200b may accommodate the substrate “W” and the ring member “R”.

The containers 200a and 200b may be transferred to the load pot 110 by a container transfer apparatus, may be loaded in the load pot 110 or unloaded from the load pot 110, and may be transferred. The container transfer apparatus may be an overhead transport apparatus (hereinafter, an OHT), but the inventive concept is not limited thereto, and the containers 200a and 200b may be transferred by various apparatuses that transfer the containers 200a and 200b. Further, an operator may directly load the containers 200a and 200b on the load pot 110 or unload the containers 200a and 200b seated in the load pot 110 from the load pot 110.

The index chamber 130 may be provided between the load pot 110 and the process executing unit 300. That is, the load pot 110 may be connected to the index chamber 130. The index chamber 130 may be maintained in an atmospheric atmosphere. The side buffer 170 that is a storage part may be installed on one side and/or the other side of the index chamber 130.

Further, the first transfer robot 150 may be provided in the index chamber 130. The first transfer robot 150 may transfer the substrate “W” and the ring member “R” between the containers 200a and 200b seated in the load pot 110, a load lock chamber 310, which will be described below, and the side buffer 170.

The process executing unit 300 may include the load lock chamber 310, a transfer chamber 330, a second transfer robot 350, the process chamber 370, and a buffer chamber 380.

The load lock chamber 310 may be disposed between the transfer chamber 330 and the index chamber 130. That is, the load lock chamber 310 may be connected to the index chamber 130 and the transfer chamber 330. The load lock chamber 310 provides a space in which the substrate “W” and/or the ring member “R” are temporarily stored. A vacuum pump (not illustrated) and a valve may be installed in the load lock chamber 310 such that an internal atmosphere of the load lock chamber 310 may be converted between an atmospheric atmosphere and a vacuum atmosphere. Since the internal atmosphere of the transfer chamber 330, which will be described below, is maintained in the vacuum atmosphere, the atmosphere of the load lock chamber 310 may be converted between the atmospheric atmosphere and the vacuum atmosphere to transfer the substrate “W” and the ring member “R” between the transfer chamber 330 and the index chamber 130.

The transfer chamber 330 may be disposed between the load lock chamber 310 and the process chamber 370. The transfer chamber 330 may be disposed between the load lock chamber 310 and the buffer chamber 380. The internal atmosphere of the transfer chamber 330 may be maintained in the vacuum atmosphere. Further, the second transfer robot 350 may be provided in the transfer chamber 330. The second transfer robot 350 may transfer the substrate “W” and the ring member “R” between the load lock chamber 310 and the process chamber 370. Further, the second transfer robot 350 may transfer the substrate “W” and the ring member “R” between the load lock chamber 310 and the buffer chamber 380. The second transfer robot 350 includes a hand 352. The second transfer robot 350 may be configured to move the hand 352 in the first direction “X”, the second direction “Y”, or the third direction “Z”. Further, the second transfer robot 350 may be configured to rotate the hand 352 about the third direction “Z”.

At least one process chamber 370 may be connected to the transfer chamber 330. Further, at least one buffer chamber 380 may be connected to the transfer chamber 330.

The process chamber 370 may receive the substrate “W” from the second transfer robot 350 provided in the transfer chamber 330 and may perform a treatment process. The process chamber 370 may be a chamber in which a process on the substrate “W” is performed. The process chamber 370 may be a liquid treating chamber in which the substrate “W” is treated by supplying a treatment liquid to the substrate “W”. Further, the process chamber 370 may be a plasma chamber in which the substrate “W” is treated by using plasma. Further, some of the process chambers 370 may be liquid treatment chambers in which the substrate “W” is treated by supplying the treatment liquid to the substrate “W”, and the other process chambers 370 may be plasma chambers in which the substrate “W” is treated by using plasma. However, the inventive concept is not limited thereto, and a substrate treating process performed in the process chamber 370 may be variously modified to known substrate treating processes. Further, when the process chamber 370 is a plasma chamber in which the substrate “W” is treated by using the plasma, the plasma chamber may be a chamber in which an etching or ashing process of removing a thin film on the substrate “W” using the plasma is performed. However, the inventive concept is not limited thereto, and a plasma treatment process performed in the process chamber 370 may be variously modified to known plasma treatment processes. A substrate treating apparatus 500 provided in the process chamber 370 will be described below.

The buffer chamber 380 may seat the substrate “W” on the ring member “R”. For example, the substrate “W” may be transferred while being seated on the ring member “R” to the buffer chamber 380. Thereafter, the substrate “W” and the ring member “R” may be separated from each other in the buffer chamber 380. Thereafter, the second transfer robot 350 may carry out the substrate “W” from the buffer chamber 380 and carry out the ring member “R” from the buffer chamber 380.

Further, the buffer chamber 380 may separate the substrate “W” seated on the ring member “R” from the ring member “R”. For example, the ring member “R” may be transferred to the buffer chamber 380 alone. Thereafter, the substrate “W” may be transferred to the buffer chamber 380 alone. Thereafter, in the buffer chamber 380, the substrate “W” may be seated on the ring member “R”. Thereafter, the second transfer robot 350 may carry out the substrate “W” seated on the ring member “R” together with the ring member “R” from the buffer chamber 380. A substrate treating apparatus 600 provided in the buffer chamber 380 will be described below.

Further, FIG. 1 illustrates an example that the transfer chamber 330 has a substantially hexagonal shape when viewed from the top, three process chambers 370 connected to the transfer chamber 330 are provided, and one buffer chamber 380 connected to the transfer chamber 330 is provided, but the inventive concept is not limited thereto. For example, the shape of the transfer chamber 330, the number of the process chambers 370, and the number of the buffer chambers 380 may be variously modified according to the necessity of the user, and the number of substrates “W” that require a treatment.

The controller 700 may control the substrate treating apparatus 1000. The controller 700 may control the index unit 100 and the process executing unit 300. The controller 700 may control the first transfer robot 150 and the second transfer robot 350. The controller 700 may control the substrate treating apparatus 500 provided in the process chamber 370 such that the substrate “W” may be treated in the process chamber 370 by using the plasma. Further, the controller 700 may control the substrate treating apparatus 600 provided in the buffer chamber 380 so that, in the buffer chamber 380, the substrate “W” is seated on the ring member “R” or the substrate “W” is separated from the ring member “R”.

Further, the controller 700 may include a process controller including a microprocessor (computer) that executes control of the substrate treating apparatus 1000, a user interface including a keyboard for inputting commands to allow an operator to manage the substrate treating apparatus 1000 and a display that visualizes and displays an operation situation of the substrate treating apparatus 1000, and a memory unit for storing a processing recipe including a control program for executing processing executed by the substrate treating apparatus 1000 under a control of the process controller or a program for executing processing in components according to various data and processing conditions. Further, the user interface and the memory unit may be connected to the process controller. The processing recipe may be stored in a memory medium of the memory unit, and the memory medium may be a hard disk or may be a transportable disk such as a CD-ROM and a DVD or a semiconductor memory such as a flash memory.

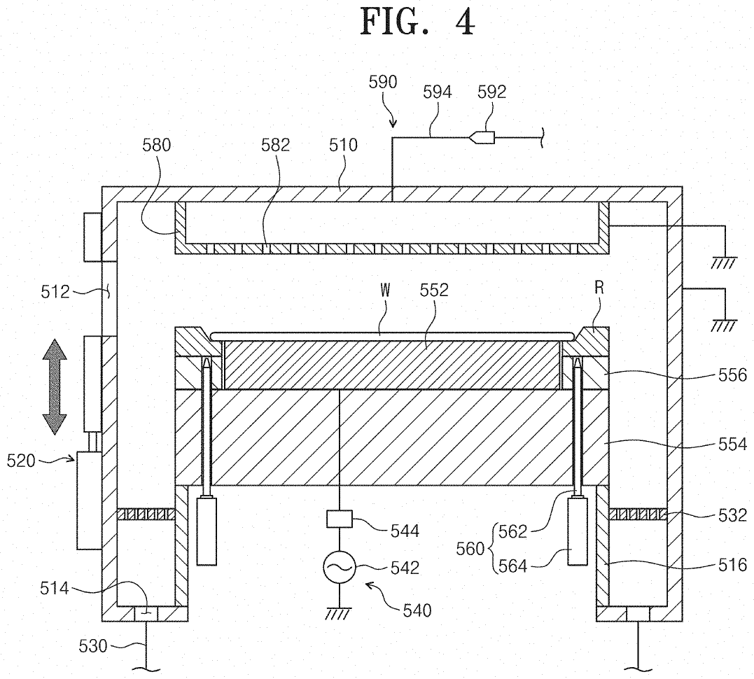

FIG. 4 is a view illustrating the substrate treating apparatus provided in a process chamber of FIG. 1. Referring to FIG. 4, the substrate treating apparatus 500 provided in the process chamber 370 will be described in detail. The substrate treating apparatus 500 may treat the substrate “W” by transferring plasma to the substrate “W”.

The substrate treating apparatus 500 may include a treatment container 510, a gate valve 520, an exhaust line 530, a power source unit 540, a support unit 550, a lift pin module 560, a baffle plate 580, and a gas supply unit 590.

The treatment container 510 may have a treatment space. The treatment container 510 may be grounded. The treatment container 510 may provide the treatment space in which the substrate “W” is treated. The treatment space of the treatment container 510 may be maintained substantially at a vacuum atmosphere when the substrate “W” is treated. An inlet port 512, through which the substrate “W” and the ring member “R” are carried in and out, may be formed on one side of the treatment container 510. The gate valve 520 may selectively open or close the inlet port 512.

An exhaust hole 514 may be formed on a bottom surface of the treatment container 510. The exhaust line 530 may be connected to the exhaust hole 514. The exhaust line 530 may exhaust a process gas supplied to the treatment space of the treatment container 510, a process by-product, and the like to an outside of the treatment container 510 through the exhaust hole 514. Further, an exhaust plate 532 may be provided at an upper portion of the exhaust hole 514 to more uniformly exhaust the treatment space. The exhaust plate 532 may substantially have a ring shape when viewed from the top. Further, at least one exhaust hole may be formed in the exhaust plate 532. The operator may select, among a plurality of exhaust plates 532 having various shapes and sizes, the exhaust plate 532 that may uniformly exhaust the treatment space and install the exhaust plate 532 at an upper portion of the exhaust hole 514.

Further, the treatment container 510 may further include a support member 516. The support member 516 may support at least a portion of a base of the support unit 550, which will be described below. For example, the support member 516 may be configured to support a lower portion of an insulation plate 554 of the support unit 550.

The power source unit 540 may generate RF power that excites the process gas supplied by the gas supply unit 590, which will be described below, in a plasma state. The power source unit 540 may include a power supply 542 and a matcher 544. The power supply 542 and the matcher 544 may be installed on an electric power transmission line. Further, the electric power transmission line may be connected to a chuck 552.

The support unit 550 may support the substrate “W” in the treatment space of the treatment container 510. The support unit 550 may include the chuck 552, the insulation plate 554, and a quartz ring 556.

The chuck 552 may have a support surface that supports the substrate “W”. The chuck 552 may support the substrate “W”, and may chuck the supported substrate “W”. For example, an electrostatic plate (not illustrated) may be provided in the chuck 552, and the chuck 552 may be an electrostatic chuck that chucks the substrate “W” using an electrostatic force. For example, the chuck 552 may be an electrode static chuck (ESC). However, the inventive concept is not limited thereto, and the chuck 552 may chuck the substrate “W” in a vacuum suction scheme. Further, the chuck 552 may be a blocking plate in which a lift pin hole that is a path through which a lift pin 562, which will be described below, moves is not formed.

The insulation plate 554 may have a circular shape when viewed from the top. The above-described chuck 552, and the quartz ring 556, which will be described below, may be placed on the insulation plate 554. The insulation plate 554 may be a dielectric body. For example, the insulation plate 554 may be formed of a material including ceramics.

The quartz ring 556 may be formed of a material including quartz. The quartz ring 556 may have a ring shape when viewed from the top. The quartz ring 556 may have a shape that surrounds the chuck 552 when viewed from the top. The quartz ring 556 may have a shape that surrounds the substrate “W” supported by the chuck 552 when viewed from the top. Further, the ring member “R” (for example, a focusing ring) may be placed on an inner upper surface of the quartz ring 556.

The ring member “R” placed on the upper surface of the quartz ring 556 may have a ring shape when viewed from the top. The ring member “R” may have a shape in which the height of an inner upper surface thereof is lower than the height of an outer upper surface thereof. A lower surface of an edge region of the substrate “W” may be placed on the inner upper surface of the ring member “R”. Further, the ring member “R” may have an inclined surface inclined upward in a direction from the center of the substrate “W” to the outside of the substrate “W” between the inner upper surface and the outer upper surface thereof. Accordingly, when the substrate “W” is placed on the inner upper surface of the ring member “R”, even when the placement location is somewhat inaccurate, as the substrate “W” slides along the inclined surface of the ring member “R”, the substrate “W” may be properly placed on the inner upper surface of the ring member “R”.

The lift pin module 560 may elevate the ring member “R” placed on the upper surface of the quartz ring 556. The lift pin module 560 may lift the lower surface of the ring member “R” in a state in which the substrate “W” is supported by the ring member “R”. The lift pin module 560 may include the lift pin 562 and a pin drive unit 564. A plurality of lift pins 562 may be provided and a plurality of pin drive units 564 that vertically move the lift pins 562, respectively, may be also provided. Further, the lift pin 562 may be disposed so as not to overlap the chuck 552 when viewed from the top. The lift pin 562 may be vertically moved along a pin hole formed in the insulation plate 554 and/or the quartz ring 556. Further, the pin drive unit 564 may be a cylinder that uses a pneumatic pressure or a hydraulic pressure, or a motor.

The baffle plate 580 may be provided above the support unit 550. The baffle plate 580 may be formed of an electrode material. At least one baffle hole 582 may be formed in the baffle plate 580. For example, a plurality of baffle holes 582 may be formed, and may be uniformly formed in a whole region of the baffle plate 580 when viewed from the top. The baffle plate 580 may allow the process gas supplied by the gas supply unit 590, which will be described below, to be uniformly delivered to the substrate “W”.

The gas supply unit 590 may supply the process gas into the treatment space of the treatment container 510. The process gas may be a gas that is excited into a plasma state by the power source unit 540, which has been described above. The gas supply unit 590 may include a gas supply source 592 and a gas supply line 594. One end of the gas supply line 594 may be connected to the gas supply source 592, and the other end of the gas supply line 594 may be connected to an upper portion of the treatment container 510. Accordingly, the process gas delivered by the gas supply source 592 may be supplied to an upper region of the baffle plate 580 through the gas supply line 594. The process gas supplied to the upper region of the baffle plate 580 may be introduced into the treatment space of the treatment container 510 through the baffle hole 582.

Hereinafter, a substrate transferring method in which the second transfer robot 350 carries the substrate “W” and the ring member “R” into the treatment space of the treatment container 510 or carries out the substrate “W” and the ring member “R” from the treatment space will be described. Further, in order to perform the substrate transferring method which will be described below, the controller 700 may control the substrate treating apparatus 1000. Hereinafter, an example in which the second transfer robot 350 carries out the substrate “W” and the ring member “R” from the treatment space of the treatment container 510 will be described.

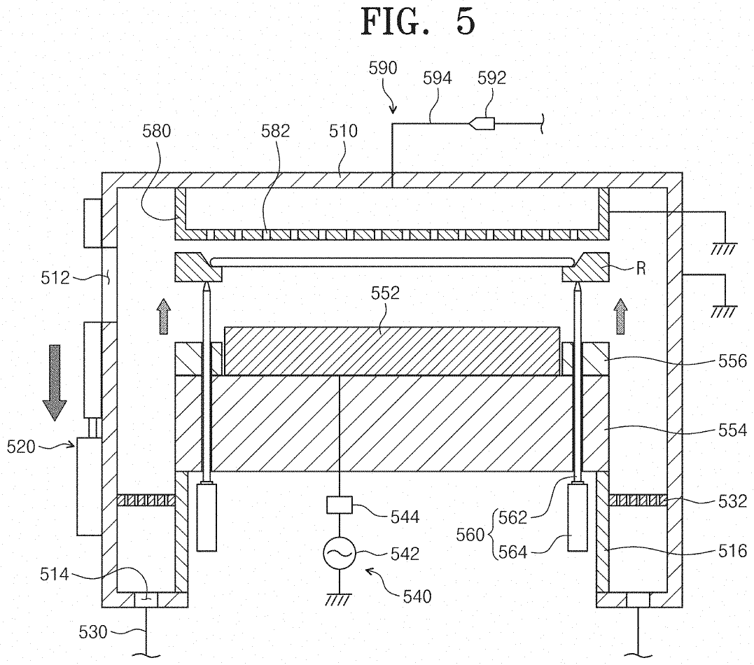

First, the controller 700 controls the lift pin module 560 so that the lift pin 562 is raised to lift the lower surface of the ring member “R” (see FIG. 5). In this case, since the substrate “W” is placed on the inner upper surface of the ring member “R”, when the lift pin 562 pushes the lower surface of the ring member “R” upward, the substrate “W” is raised while being supported by the ring member “R”.

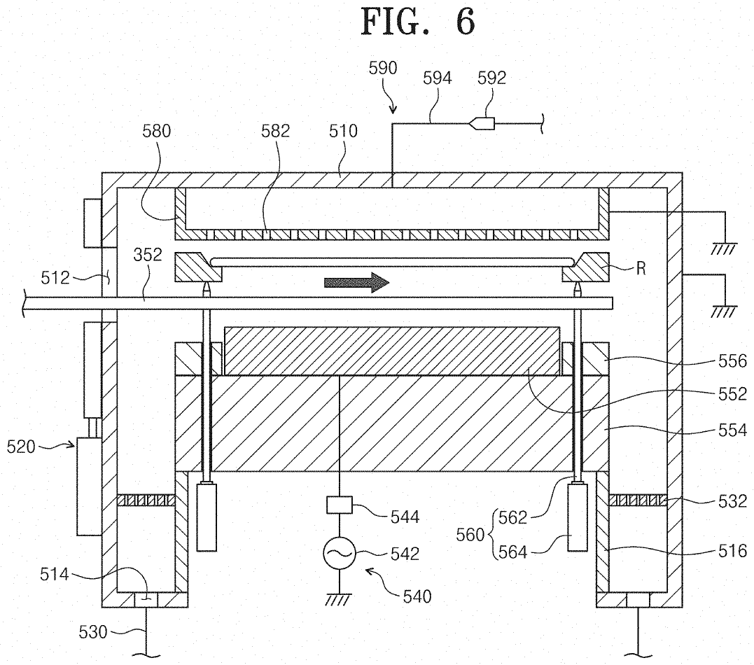

Thereafter, the hand 352 of the second transfer robot 350 is moved into the treatment space of the treatment container 510 (see FIG. 6). For example, the hand 352 of the second transfer robot 350 is moved into a lower portion of the ring member “R”.

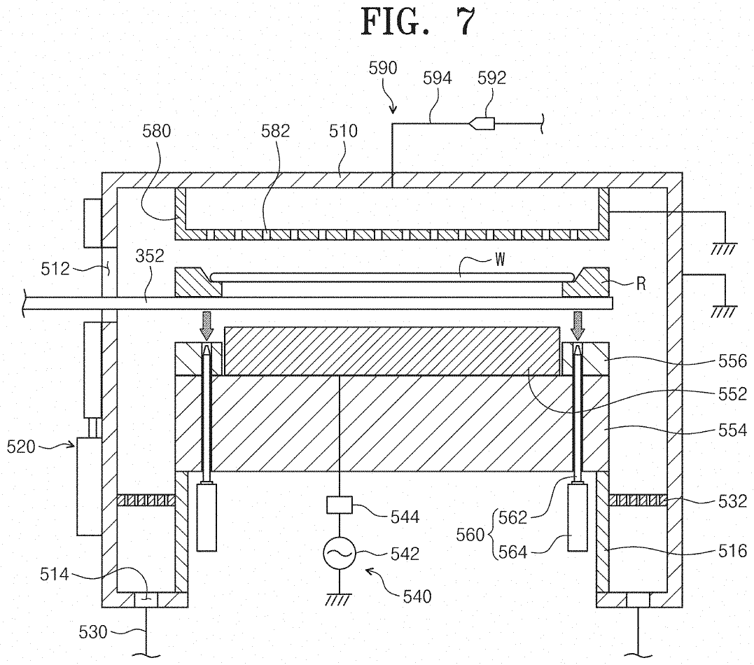

Thereafter, the controller 700 controls the lift pin module 560 so that the lift pin 562 is lowered, and thus the ring member “R” on which the substrate “W” is seated may be seated on an upper surface of the hand 352 of the second transfer robot 350 (see FIG. 7).

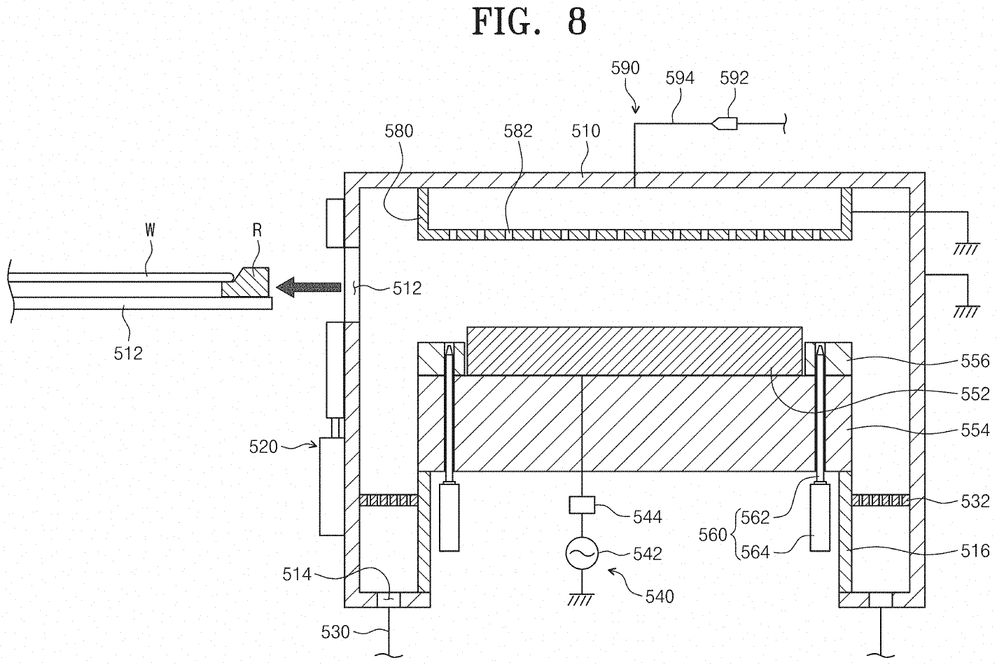

Thereafter, the controller 700 carries out the substrate “W” from the treatment space of the treatment container 510 in a state in which the substrate “W” is supported by the ring member “R” on the upper surface of the hand 352 (see FIG. 8).

When the second transfer robot 350 carries the substrate “W” into the treatment space of the treatment container 510, the substrate “W” is carried into the treatment space in an order opposite to the above-described carrying-out sequence. For example, when the second transfer robot 350 carries the substrate “W” into the treatment space, the hand 352 of the second transfer robot 350 is moved into the treatment space while supporting the ring member “R” on which the substrate “W” is seated. The lift pin 562 of the lift pin module 560 is raised to support and push upward the lower surface of the ring member “R” on which the substrate “W” is seated and to drop the hand 352 and the ring member “R”. Thereafter, the hand 352 moves out of the treatment space of the treatment container 510, the lift pin 562 is then lowered, and thus the substrate “W” may be seated on a support surface of the chuck 552.

In this way, in the substrate treating apparatus according to the embodiment of the inventive concept, the lift pin hole is not formed in the chuck 552. Since the lift pin hole is not formed in the chuck 552, an arcing phenomenon that may occur when the lift pin hole is formed in the chuck 552 may be minimized. Accordingly, the substrate “W” in the treatment space may be treated more efficiently.

Further, the substrate “W” is raised or lowered only by the lift pin module 560 in a state in which the substrate “W” is supported by the ring member “R”. That is, in the substrate treating apparatus 500 provided in the process chamber 370, it is difficult to seat the substrate “W” on the ring member “R” or separate the substrate “W” from the ring member “R”. Accordingly, while being supported by the ring member “R”, the substrate “W” is always carried into the treatment space of the treatment container 510 or is carried out from the treatment space. That is, when the substrate “W” is carried in or out, the hand 352 always passes through the inlet port 512 while supporting the lower surface of the ring member “R” supporting the substrate “W”. In this case, the ring member “R” is not placed on a lateral portion of the chuck 552 during a time between a time when the completely treated substrate “W” is carried out from the treatment container 510 and a time when the untreated substrate “W” is carried into the treatment container 510. Impurities such as polymer generated while the substrate “W” is treated may be attached to the lateral portion of the chuck 552. The substrate treating apparatus 1000 according to the embodiment of the inventive concept may perform a dry cleaning process (e.g., In-Situ Drycleaning) of removing impurities attached to the chuck 552 by supplying a cleaning gas to the lateral portion of the chuck 552 by a cleaning gas supply member (not illustrated) of the substrate treating apparatus 500 provided in the process chamber 370 while the ring member “R” is not seated on the lateral portion of the chuck 552.

As described above, in the substrate transferring method according to the embodiment of the inventive concept, when the substrate “W” passes through the inlet port 512 of the treatment container 510, the substrate “W” is always transferred while being supported by the ring member “R”. However, in general, the ring member “R” and the substrate “W” are accommodated in separate containers 200a and 200b, respectively. That is, in order to transfer the substrate “W” carried out from the containers 200a and 200b to the process chamber 370 in a state in which the substrate “W” is supported by the ring member “R”, a process of supporting the substrate “W” on the ring member “R” is required. In contrast, in order to transfer the substrate “W” carried out from the process chamber 370 to the containers 200a and 200b in a state in which the substrate “W” is separated from the ring member “R”, a process of separating the ring member “R” and the substrate “W” from each other is required.

Accordingly, the substrate treating apparatus 1000 according to the embodiment of the inventive concept includes the buffer chamber 380. The buffer chamber 380 may be provided with the substrate treating apparatus 600 that may seat the substrate “W” on the ring member “R” or separate the ring member “R” and the substrate “W” from each other.

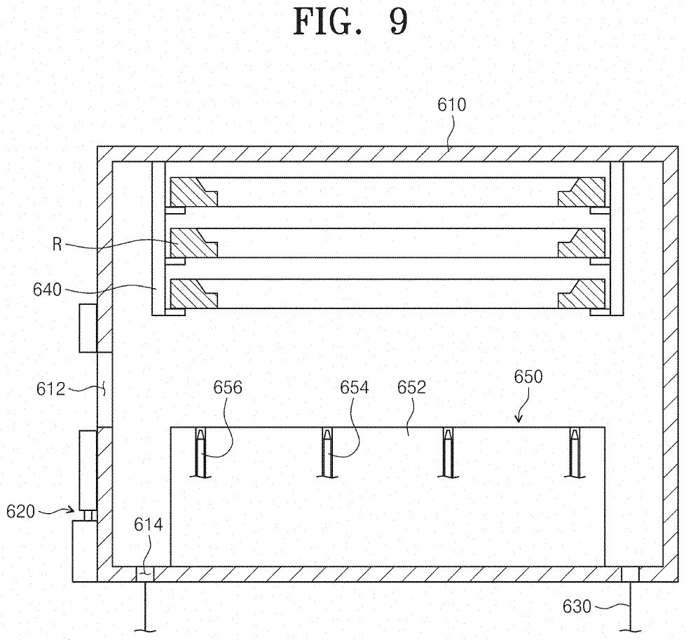

FIG. 9 is a view illustrating the substrate treating apparatus provided in the buffer chamber of FIG. 4. Referring to FIG. 9, the substrate treating apparatus 600 provided in the buffer chamber 380 may include a housing 610, a blocking member 620, a discharge line 630, a support shelf 640, and a separation unit 650.

The housing 610 may have an internal space 611. The housing 610 may provide the internal space 611 in which the substrate “W” is seated on the ring member “R” or the ring member “R” and the substrate “W” are separated from each other. An opening 612 that is selectively opened or closed by the blocking member 620 may be formed on one side of the housing 610. The blocking member 620 may be a gate valve. Further, a discharge hole 614 may be formed in the housing 610, and the discharge hole 614 may be connected to the discharge line 630. Accordingly, impurities such as particles remaining in the internal space 611 of the housing 610 may be discharged to the outside of the housing 610 through the discharge hole 614.

Further, the support shelf 640 may be provided in the internal space 611 of the housing 610. The support shelf 640 may accommodate the ring member “R” in the internal space 611. For example, the ring member “R” accommodated in the support shelf 640 may be an unused ring member “R”.

The separation unit 650 may seat the substrate “W” on the ring member “R” and separate the substrate “W” from the ring member “R”. The separation unit 650 may include a support plate 652, a first lift pin 654, and a second lift pin 656.

The support plate 652 may have a circular shape when viewed from the top. The support plate 652 may have a seating surface on which the ring member “R” is seated. The seating surface may be in contact with only the lower surface of the ring member “R” and may be spaced apart from the lower surface of the substrate “W”. Further, the first lift pin 654 may be disposed in a central region of the support plate 652 when viewed from the top, and may lift the substrate “W” among the substrate “W” and the ring member “R”. Further, the second lift pin 656 may be disposed in an edge region of the support plate 652 when viewed from the top, and may lift the ring member “R” in a state in which the ring member “R” or the substrate “W” is seated.

Hereinafter, a separation process of separating the ring member “R” and the substrate “W” from each other will be described. A coupling process of coupling the ring member “R” and the substrate “W” may be performed in a reverse order of the separation process which will be described below. Further, in order to perform the separation process (or the coupling process) which will be described below, the controller 700 may control the substrate treating apparatus 600 provided in the buffer chamber 380.

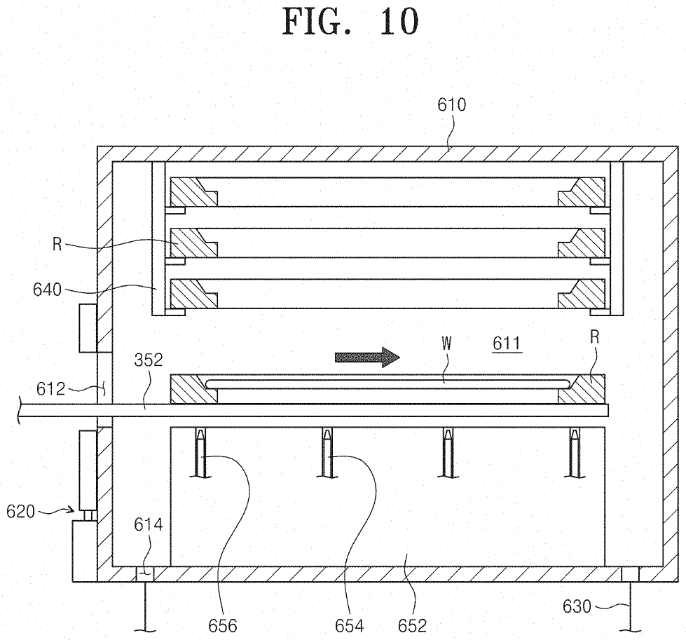

First, the hand 352 of the second transfer robot 350 may be moved into the internal space 611 of the housing 610 while supporting the ring member “R” in a state in which the substrate “W” is supported (see FIG. 10). The hand 352 may be moved into an upper portion of the support plate 652. Further, the hand 352 may transfer the ring member “R”, in a state in which the substrate “W” is supported, to a location in which the second lift pin 656 overlaps the ring member “R” when viewed from the top.

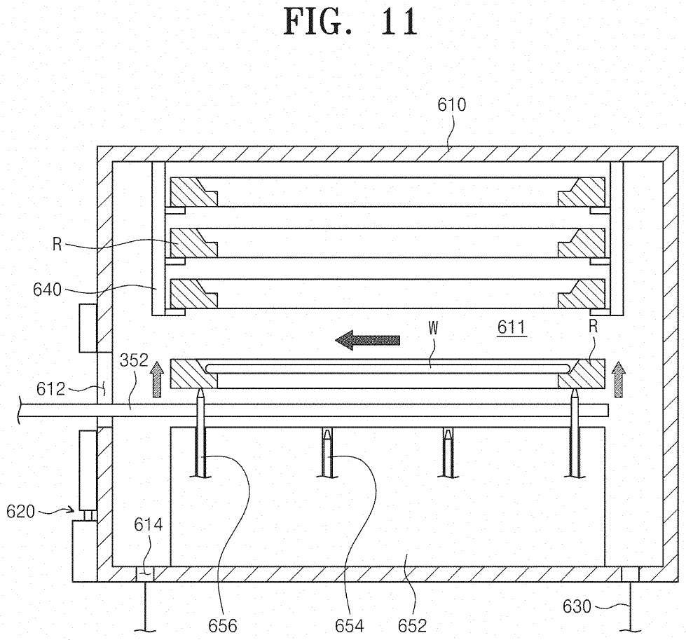

Thereafter, the second lift pin 656 is raised to space the ring member “R”, in a state in which the substrate “W” is supported, apart from the hand 352, and when the ring member “R” is spaced apart from the hand 352, the hand 352 may escape from the internal space 611 of the housing 610 through the opening 612 (see FIG. 11).

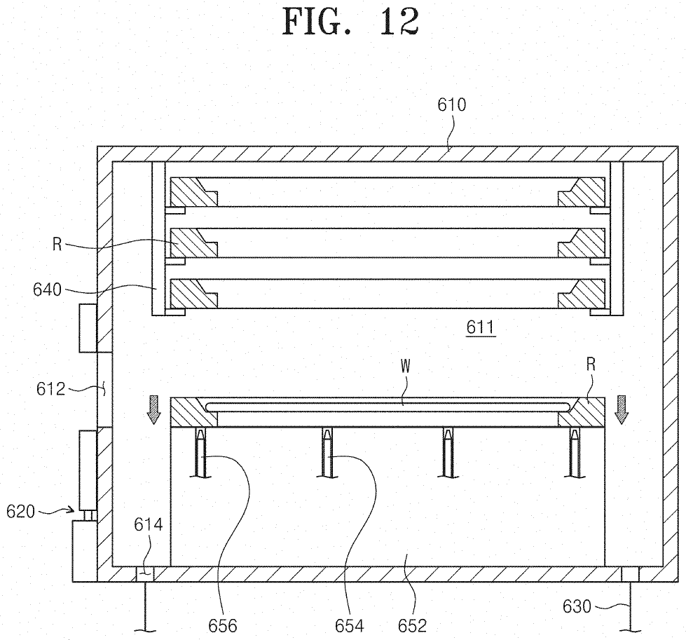

Thereafter, the second lift pin 656 may be lowered to seat the ring member “R”, in a state in which the substrate “W” is supported, on the seating surface of the support plate 652 (see FIG. 12).

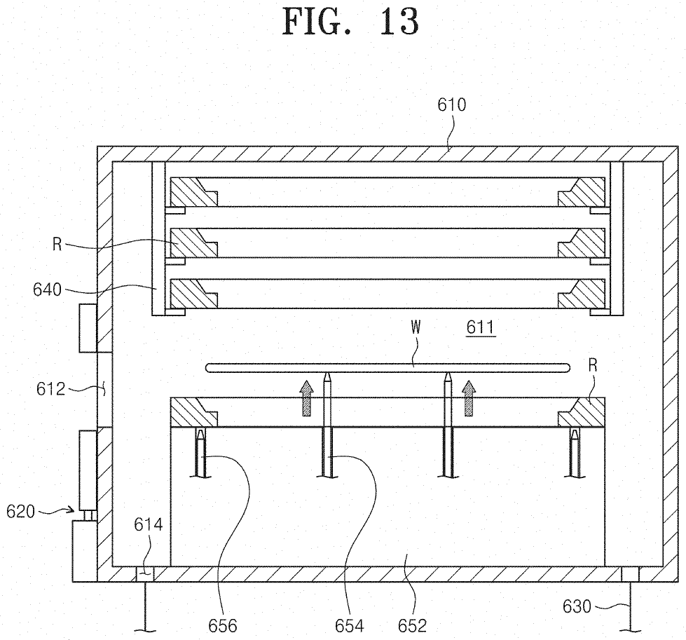

Thereafter, the first lift pin 654 may be raised to separate the substrate “W” from the ring member “R” (see FIG. 13).

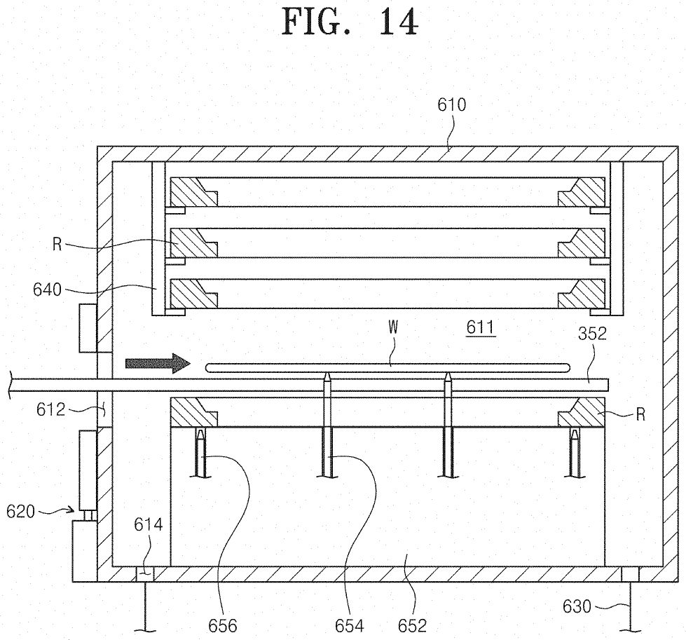

Thereafter, the hand 352 of the second transfer robot 350 may be moved into the internal space 611 of the housing 610 (see FIG. 14). In this case, the hand 352 may be moved into a lower portion of the substrate “W”.

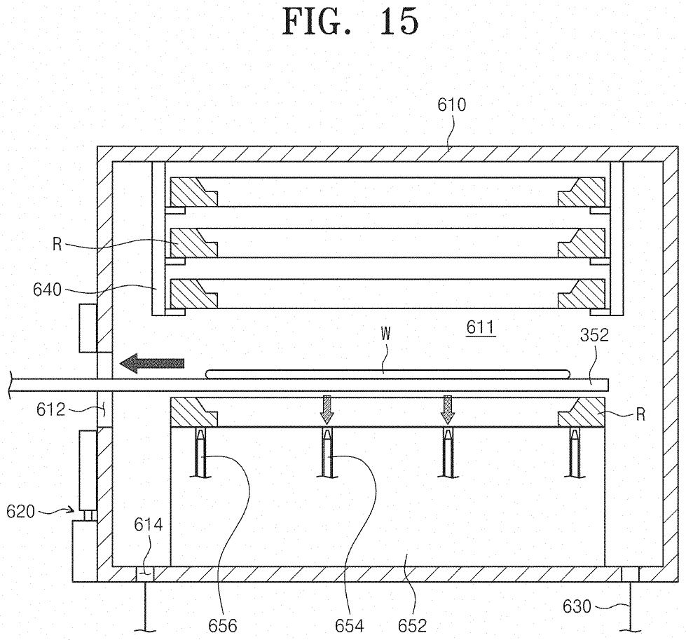

Thereafter, the first lift pin 654 may be lowered to seat the substrate “W” on the upper surface of the hand 352, and the hand 352 may carry out the substrate “W” from the internal space 611 of the housing 610 (see FIG. 15).

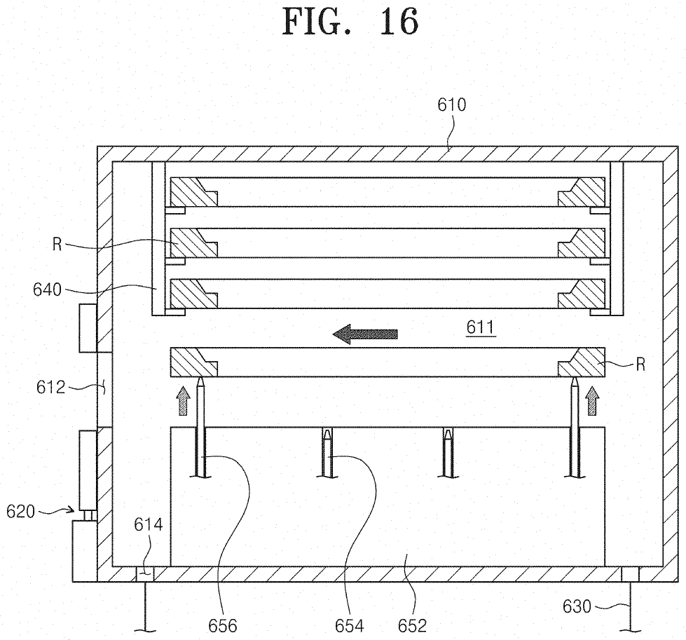

Thereafter, the second lift pin 656 may be raised to space the ring member “R” apart from the seating surface of the support plate 652 (see FIG. 16).

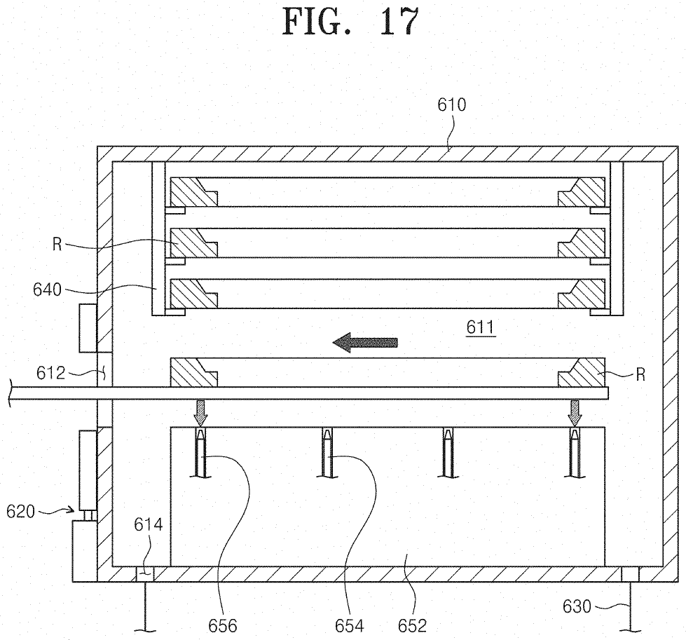

Thereafter, the hand 352 of the second transfer robot 350 may be moved into the internal space 611 of the housing 610. For example, the hand 352 may be moved into the lower portion of the ring member “R”. Thereafter, the second lift pin 656 may be lowered to seat the ring member “R” on the hand 352. Thereafter, the hand 352 may carry out the ring member “R” from the internal space 611 of the housing 610 (see FIG. 17).

In this way, the buffer chamber 380 according to the embodiment of the inventive concept may perform the coupling process for supporting the substrate “W” on the ring member “R” and the separation process for separating the ring member “R” from the substrate “W”, and thus when the substrate “W” is carried into or out form the process chamber 370, the substrate “W” may always be supported by the ring member “R”.

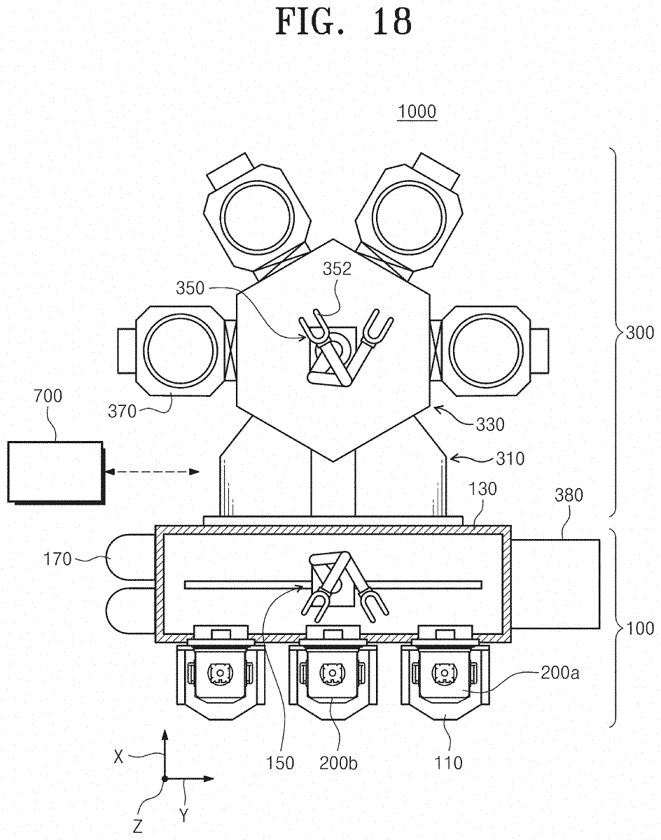

It has been described in the above-described example that the buffer chamber 380 is connected to the transfer chamber 330, but the inventive concept is not limited thereto. For example, as illustrated in FIG. 18, the buffer chamber 380 may be connected to one side of the index chamber 130. Further, in contrast, the buffer chamber 380 may be provided between the transfer chamber 330 and the index chamber 130, that is, at a location of the load lock chamber 310. Further, the substrate treating apparatus 600 provided in the buffer chamber 380 may be also provided in the load lock chamber 310.

According to the embodiment of the inventive concept, a substrate may be efficiently treated.

Further, according to the embodiment of the inventive concept, the occurrence of an arcing phenomenon may be minimized.

Further, according to the embodiment of the inventive concept, the attachment of impurities to a chuck of a substrate treating apparatus may be minimized or the chuck may be effectively cleaned.

Further, according to the embodiment of the inventive concept, when the substrate is lifted from the chuck, the occurrence of twisting or cracking of the substrate may be minimized.

The effects of the inventive concept are not limited to the above-mentioned effects, and the unmentioned effects can be clearly understood by those skilled in the art to which the inventive concept pertains from the specification and the accompanying drawings.

The above detailed description exemplifies the inventive concept. Furthermore, the above-mentioned contents describe the exemplary embodiment of the inventive concept, and the inventive concept may be used in various other combinations, changes, and environments. That is, the inventive concept can be modified and corrected without departing from the scope of the inventive concept that is disclosed in the specification, the equivalent scope to the written disclosures, and/or the technical or knowledge range of those skilled in the art. The written embodiment describes the best state for implementing the technical spirit of the inventive concept, and various changes required in the detailed application fields and purposes of the inventive concept can be made. Accordingly, the detailed description of the inventive concept is not intended to restrict the inventive concept in the disclosed embodiment state. Furthermore, it should be construed that the attached claims include other embodiments.

1. A substrate treating apparatus comprising:
a process chamber in which a substrate is treated; and
a transfer robot configured to transfer the substrate and a focusing ring provided in a treatment space of the process chamber to the treatment space and having a hand,
wherein the process chamber includes:
a treatment container configured to provide the treatment space;
a chuck having a support surface supporting the substrate in the treatment space; and
a lift pin module configured to lift a lower surface of the focusing ring in a state in which the substrate is supported by the focusing ring, and
wherein the chuck is provided as a blocking plate in which a lift pin hole is not formed.

2. The substrate treating apparatus of claim 1, wherein the treatment container has an inlet port in which the focusing ring and the substrate are carried,
wherein the substrate treating apparatus further comprises a controller, and
wherein the controller controls the transfer robot and the lift pin module so that, when the substrate is carried into the treatment space or carried out from the treatment space, the substrate passes through the inlet port in a state in which the hand supports the lower surface of the focusing ring configured to support the substrate.

3. The substrate treating apparatus of claim 1, wherein the treatment container has an inlet port in which the focusing ring and the substrate are carried,
wherein the substrate treating apparatus further comprises a controller, and
wherein the controller controls the transfer robot and the lift pin module so that, when the substrate passes through the inlet port, the substrate always passes through the inlet port while being supported by the focusing ring.

4. The substrate treating apparatus of claim 1, wherein the lift pin module includes: a lift pin disposed so as not to overlap the chuck when viewed from a top; and
a pin drive unit configured to vertically move the lift pin.

5. The substrate treating apparatus of claim 4, wherein the process chamber further includes an insulation plate disposed below the chuck.

6. The substrate treating apparatus of claim 1, wherein a height of an inner upper surface of the focusing ring is smaller than a height of an outer upper surface of the focusing ring, and thus a lower surface of an edge region of the substrate is placed on the inner upper surface of the focusing ring.

7. The substrate treating apparatus of claim 6, wherein the focusing ring has an inclined surface inclined upward in a direction from a center of the substrate to an outside of the substrate between the inner upper surface and the outer upper surface of the focusing ring.

8. The substrate treating apparatus of claim 1, further comprising:
a buffer chamber configured to seat the substrate on the focusing ring or separate the focusing ring and the substrate from each other.

9. The substrate treating apparatus of claim 8, wherein the buffer chamber includes: a support plate having a seating surface on which the focusing ring is seated;
a first lift pin disposed at a central region of the support plate when viewed from a top and configured to lift the substrate; and
a second lift pin disposed at an edge region of the support plate when viewed from the top and configured to lift the focusing ring.

10. The substrate treating apparatus of claim 9, wherein the buffer chamber further includes a support shelf accommodating the focusing ring.

11. The substrate treating apparatus of claim 8, further comprising:
a transfer chamber in which the transfer robot is provided,
wherein the process chamber and the buffer chamber are connected to the transfer chamber.

12. The substrate treating apparatus of claim 8, further comprising:
an index unit including a load pot on which a container configured to accommodate the substrate and/or the focusing ring is seated and an index chamber connected to the load pot; and
a process executing unit having the process chamber, a transfer chamber in which the transfer robot is provided, and a load lock chamber disposed between the index chamber and the transfer chamber,
wherein the buffer chamber is connected to the index chamber.

13. A substrate treating apparatus comprising:
a process chamber in which a substrate is treated;
a transfer robot configured to transfer the substrate and a ring member provided in a treatment space of the process chamber to the treatment space and having a hand; and
a controller,
wherein the process chamber includes:
a treatment container configured to provide the treatment space and having an inlet port in which the substrate and the ring member are carried;
a chuck having a support surface for supporting the substrate in the treatment space; and
a lift pin module configured to push a lower surface of the ring member upward in a state in which the substrate is supported by the ring member, and
wherein the controller controls the transfer robot and the lift pin module so that, when the substrate is carried in the treatment space or is carried out from the treatment space, the substrate always passes through the inlet port while being supported by the ring member.

14. The substrate treating apparatus of claim 13, wherein the lift pin module includes:
a lift pin disposed so as not to overlap the chuck when viewed from a top; and
a pin drive unit configured to vertically move the lift pin.

15. The substrate treating apparatus of claim 13, further comprising:
a buffer chamber configured to seat the substrate on the ring member or separate the substrate from the ring member.

16. The substrate treating apparatus of claim 15, wherein the buffer chamber includes:
a support plate having a seating surface on which the ring member is seated;
a first lift pin disposed in a central region of the support plate when viewed from a top and configured to push a lower surface of the substrate upward; and
a second lift pin disposed in an edge region of the support plate when viewed from the top and configured to push the lower surface of the ring member upward.

17.-20. (canceled)
